(19) United States
(12) Patent Application Publication
(10) Pub. No.: US 2005/0167772 A1
(43) Pub. Date: Aug. 4, 2005

(54) Gate for information processing

(76) Inventors: Arthur Marshall Stoneham, Wallingford Oxford (GB); Andrew James Fisher, London (GB); Philip Thornton Greenland, Oxfordshire (GB)

Correspondence Address: WENDEROTH, LIND & PONACK, L.L.P., 2033 K STREET N. W., SUITE 800, WASHINGTON, DC, 20006-1021, US

(21) Appl. No.: 10/506,471

(22) PCT Filed: Mar. 3, 2003
(86) PCT No.: PCT/GB03/00896

(30) Foreign Application Priority Data
Mar. 4, 2002 (GB) 0205011.0

(51) Int. Cl. H01L 31/0232

(52) U.S. Cl. 257/432

(57) ABSTRACT

A gate for quantum computing is disclosed based on the use of electronic excitation to control the interaction between the components of the computer in which quantum information is encoded. A means to select which components of the computing system are to interact, and hence to enable quantum information to be passed systematically around an array of gates constituting a quantum computer is also disclosed.

This invention concerns a gate for information processing, such as a computer gate, particularly for a quantum computer.

Traditional electronic computers represent numbers in binary form, encoding them in terms of 0's and 1's, so-called bits. These bits are normally manipulated as electrical signals, enabling computations to be performed with (classical) logical gates. A typical (classical) logic gate is an electronic device which takes two or more inputs (e.g. a pair of electrical signals, 0's and 1's) and delivers an output, a single signal (0 or 1) whose value depends on the inputs and the type of gate. The value of the output is related to traditional logical combinations of the inputs, and gates are characterized by the logical operation they realize. A classical digital computer comprises gates connected to form a complex network, so that the outputs from some become inputs to others. They perform arithmetic operations by converting an initial sequence of electrical signals (representing numerical input) into a final sequence (representing an answer). However, if the set of gate types available for constructing these networks is restricted, then, even with an unlimited supply of gates from the set, it may be logically impossible to construct a network capable of performing all arithmetic operations. In contrast, a set of gate types sufficient to enable all arithmetic operations to be done is called universal. The power of modem digital computers is largely due to the capability to design and manufacture universal sets of gates connected into pre-specified networks. There are two other important components: devices for setting the input and for reading the output.

These gates are usually fabricated using Si-based technology. In any chosen embodiment of a quantum computer, there are clearly some benefits in devising a system which could be integrated with the Si and optical fibre technology used in conventional computing and information technologies.

Quantum computers also have three components, namely (1) a means of preparing the input, that is, of making the appropriate combination of initial quantum states, (2) a network of quantum gates designed to perform the appropriate arithmetic and logic operations, and (3) a means of interrogating the final quantum state, that is a means of reading the output.

Quantum computers encode numbers as qubits, written in conventional quantum mechanical notation as |q>. These are the quantum mechanical analogue of classical bits. Like classical bits they have two fundamental states, conventionally designated as the quantum mechanical states |0> and |1>. However, in contrast to the classical case, the laws of quantum mechanics permit the qubit to exist in a so-called linear combination of its fundamental states, and one writes |q>=a|0>+b|1>. The laws of quantum mechanics put some restrictions on the values a and b may take, but, nevertheless the quantum mechanical qubit, determined by a and b, contains more information than its classical analogue.

Just as classical gates take classical bits as input and return classical bits as output, so quantum gates take qubits as input and return qubits as output. Slightly different terminology is useful. Rather than thinking of qubits flowing into and out of a quantum gate it is better to think of an initial pair of qubits (the input) being set, and then the gate being operated according to a gate protocol to produce the output, a final pair of qubits which result from the initial qubits and the gate protocol. The laws of quantum mechanics require that the gate protocol must not depend on the value of the input qubits. A gate which operates on pairs of qubits is often called a J-gate, and we shall use this terminology.

An important feature of such gates is their ability to produce entanglement. This is a special quantum mechanical correlation between two or more qubits, and it is known that some of the powerful quantum algorithms require entanglement for their proper operation.

Quantum computers also require so-called A-gates. These operate on single qubits, to change the values of a and b in the expression given above. They do not produce entanglement.

Operations on a chosen qubit can be challenging. A specific problem arises if one needs to access individual qubits using electromagnetic or ultrasonic radiation, because the spatial resolution L is of the order of the wavelength involved. Whilst there are ways to reduce this somewhat, the volume L³ will normally contain a lot of centres in any solid-state realisation of qubits. For example, if L is 500 nm, the volume will contain about 10¹⁰ atoms, or 10⁴ centres if present in an atomic concentration of 1 in 10⁶. There is usually no advantage in going to more dilute systems, because the qubits will have to interact within any quantum computer.

As with classical computers there are particular sets of gates that are universal, in the sense that they can be combined to mimic the effect of any other possible combination of gates. It is known that the combination of arbitrary single-qubit gates (A gates) with a single entanglement-producing two-qubit gate (J-gate) constitutes such a universal set.

In theory, quantum computers have the potential to do certain calculations that cannot be efficiently performed on (classical) digital computers. These include the rapid factorisation of very large numbers, which is significant for decryption, special searches of directories, and the accurate simulation of other quantum-mechanical systems. Other significant types of calculation are likely to emerge.

The power of quantum computation resides in the ability to construct entangled states that are general combinations of |0> and |1> states for each qubit, and to construct arbitrary operations on these states using the quantum gates. For a computer with N qubits, there are 2^{N} such combinations. However the quantum information residing in such a state is lost if the state is allowed to interact with its environment; this phenomenon is known as decoherence, and the timescale for its operation as the decoherence time. The operation of any quantum computer must take place within the decoherence time if the power of the quantum operations in processing information is to be fully utilized. The effective decoherence time can be prolonged by exploiting so-called error correction algorithms within the quantum computer.

Many proposed physical realisations of qubits comprise nuclear or electronic spins. For a spin S=½, there are just two states in a magnetic field, and these correspond to the quantum mechanical states |0> and |1>. Many nuclei have larger spins, and the electronic spin states of ions in solids can often be larger; in such cases there are more than two states of the spin. There have been suggestions (see references below) that systems (specifically, free atoms) with large spins might have advantages, since more sophisticated gates are possible, or the potential for error correction using redundancy. The disadvantages are that it has proved hard both to find a suitable system and to arrange to carry out arbitrary manipulations of the state of the spins. One further difficulty is the “do nothing problem”. Whereas a classical bit will stay in the same state if left alone, a qubit in a real quantum computer will evolve unless it is in an exact eigenstate, which will not normally be the case. Some sort of error correction will be needed even for those qubits which should do nothing.

In the choice of physical realisations there is a constant tension between two competing requirements. On the one hand, to produce entanglement and perform computations there must be physical interactions between the entities constituting the qubits. For the operations to be rapid, there must be some interactions which are not too weak. On the other hand, one would like to minimize the interactions with the external world, as these would lead to decoherence. The interactions which commonly cause difficulty include magnetic dipole-dipole interactions and interactions with lattice vibrations.

A number of realisations of quantum gates have been suggested. Solid-state implementations are especially desirable, since they might be integrated with current technologies. A review of six proposals for solid-state quantum comouting is given in G P Berman, G D Doolen, V I Tsifrinovic 2000 Superlattices and Microstructures 27 (2/3). The proposals include ideas involving (a) superconducting systems, (b) quantum dots, (c) electron spins interacting by exchange, (d) nuclear spins interacting via electrons, (e) nuclear spins in a lattice, (f) magnetic force microscopy. Other proposals, not described by Berman et al, include: include (g) Barnes et al 2000 Phys Rev B62 8410 (electron spins in channels created by surface acoustic waves); (h) Leuenberger and Loss 2001 Nature 410 789 (Electron spins in magnetic clusters); (i) Bonadeo et al 1998 Science 1473 (entanglement of two excitons in a dot). Other proposals have been based on atom traps, the use of photon polarisations, and other non-solid state realisations.

Many of these realisations control the qubit-qubit interaction by engineering a reduction in the naturally strong force between them. Thus, the quiescent state of the gate is only maintained by artificial intervention. This leads to problems, both with the maintenance of quantum coherence during the quiescent phases of the gate's operation and, since the reduction of interaction is not always perfect, with contrast between the non-operating and operating modes of the gate.

Certain other quantum computers require that dopant atoms are placed very precisely at specific locations in the device. This is technically very difficult, and even thermal diffusion may lead to problems if the device is to be used over a period of time.

An object of the present invention is to alleviate any or all of the above problems.

Accordingly the invention provides a gate for quantum information processing comprising:
at least two units each having a plurality of states useable for representing quantum information; and
an electron system having at least a first state and a second state, which states provide different amounts of interaction between said units, wherein the electron system is switchable by means of electromagnetic radiation between the first and second states to control the interaction between the units.

An advantage of the invention is that it needs no external electrodes to manipulate the interaction between the qubits. Such electrodes would be a source of potential fluctuations, and hence of decoherence. It is therefore possible to isolate the qubit donors sufficiently, so that the qubits are encoded in electron spin rather than nuclear spin. This has the advantage that the manipulations of the quantum state can be performed much more rapidly. The choice of nuclear or electronic spin will be based on the detailed parameters of a specific model and on the operating conditions.

A further advantage comes from the fact that there is no need for the control electron system to be of the same character as the qubit (information-representing unit). What is needed is a substantial change in the nature of the interaction of between the units through a change in wavefunction of a control electron system. The change might just as readily involve excitation from the compact f-states of a rare-earth ion to a more extended s or d state.

Preferably the donor of the control electron(s) is a deep centre, then the excitation energy can be reasonably large and, in particular, much larger than thermal energies at ambient temperatures (which, at room temperature, are typically 0.025 eV). So far as this gate is concerned, room temperature operation is possible.

A further advantage of the larger excitation energy is that the wavelength needed for excitation will be shorter, so that a diffraction-limited laser will access a smaller volume and will interact with fewer control electron systems. This assists in singling out specific gates (see below).

A fourth advantage concerns the “do nothing” problem. The contrast between the “off” (control donor electron system in its ground state) and “on” (excited control of the electron system) can be made extremely large by a suitable choice of states, so there is less need to take special action to ensure the qubit is unaltered when it should remain so.

A further aspect of the invention provides an array of gates, for quantum information processing, comprising:
means for applying at least one field over the array, which field shifts the energy of transitions used to control states, and wherein the or each field varies spatially, so that different portions of the array are selectively controllable.

The invention also provides a method of selectively controlling gates in an array of gates, for quantum information processing, comprising:
applying at least one field over the array, which field shifts the energy of transitions used to control states, and wherein the or each field varies spatially, so that different portions of the array are selectively controllable

These aspects of the invention enable gates to be singled out by a combination of spatial position and energy. The imposed field can be an applied field, such and an electric or magnetic or stress field, or a transient field, such as an ultrasonic pulse, or a built-in microstructure, such as from misfit dislocations.

An advantage of this approach is emphasised, namely that there are many ways to combine frequency and spatial discrimination. The combination enables the operation of effective A-gates and the controlled movement of quantum information around a quantum computer. Specific control donors are identified by a combination of position and energy.

The gate controlled by excitation according to embodiments of this invention is distinctly different from the quantum dot ideas of Loss and DiVincenzo [Phys Rev A vol 57 120-126 (1998)]. Although both involve excited states, they do so in fundamentally different ways, as the following table shows:

| | | Preferred embodiments of the |
|---|---|---|
| Feature | Quantum dot idea | present invention. |
| Two-level | Ground and excited state | Electron spin or nuclear spin. |
| component | of dot. Create this by | Exists without excitation |
| of qubit. | suitable excitation | |
| A-gate: | Mainly by excitation and | Use of magnetic resonance, |
| control of | electric fields localised on a | for example, plus other fields |
| components | particular dot | and the means to localise |
| | | excitation to the component |
| J-gate: | Electric field (static, apart | Excitation of an electron |
| control of | from switching on and | which changes the |
| interactions | off to create the dipole | interactions |
| | moments which interact) | |

Embodiments of the invention will now be described, by way of example only, with reference to the accompanying drawings, in which:

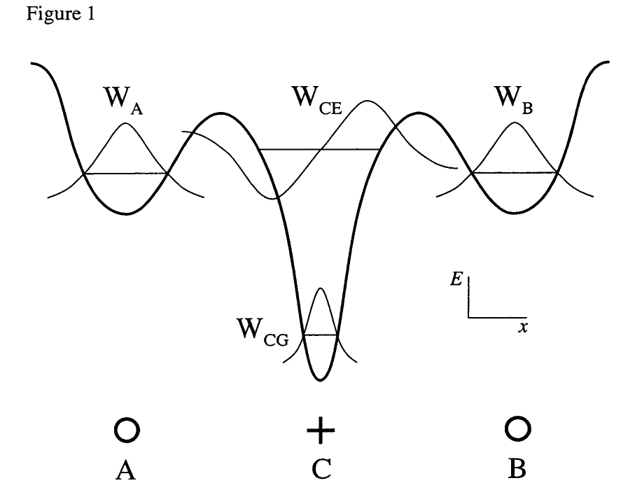

FIG. 1 is a schematic diagram of a gate in which electron spins A, B provide the qubits, and control is achieved by the excitation of a control electron, C, which has an excited state wavefunction which leads to a significant interaction between electrons A, B;

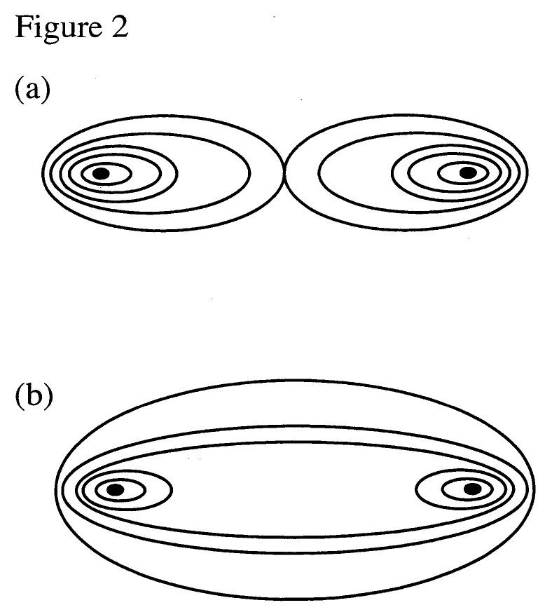

FIGS. 2(a) and (b) are sketches of the electron density in the ground and excited states of a 2-electron qubit system according to a different embodiment of the invention;

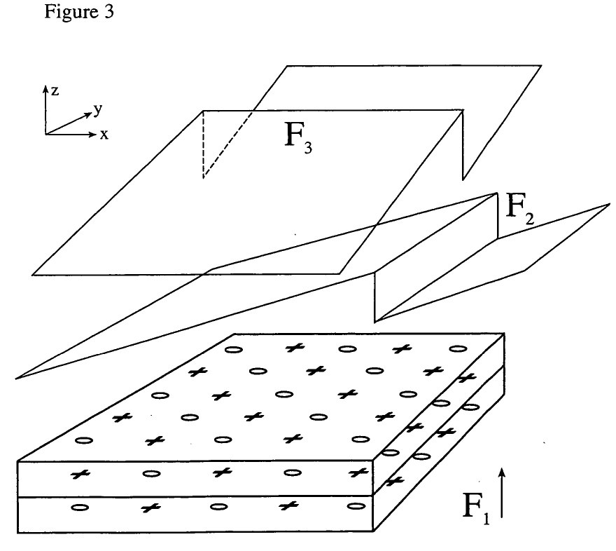

FIG. 3 illustrates the application of up to three imposed fields which vary over the region containing the gate and causes the characteristic energy of the gate to vary from one place to another in a systematic way; and

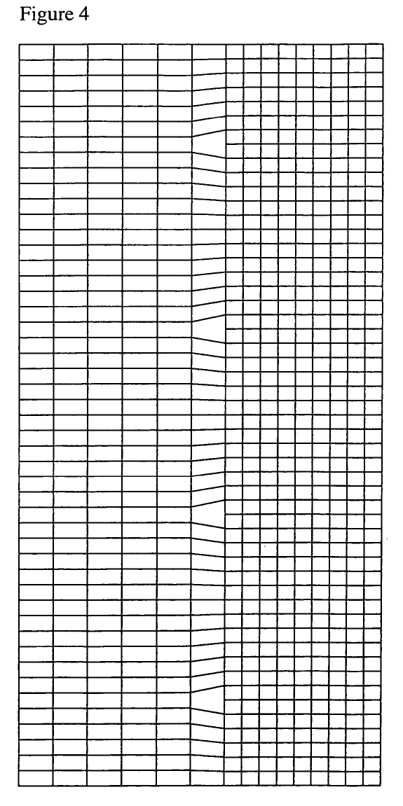

FIG. 4 illustrates example of misfit dislocations, where there are approximately regular extra atomic planes or missing atomic planes so as to maintain registry between two materials with slightly different interatomic spacings at an interface, and which provides a varying stress field.

FIG. 1 shows schematically a system embodying the invention. At the bottom of the figure, two quantum information-representing units for encoding qubits are represented by the circles A and B. Disposed between A and B is a control electron system indicated by cross C. The upper portion of the figure shows a plot of energy E as a function of lateral position x through the gate system. Superimposed on the energy plot are wavefunctions of the components of the system which will be discussed below. In this embodiment the qubits A and B are encoded as the spin states of spin ½ particles, which, for all practical purposes are isolated from their environment. In this exemplary embodiment the spin ½ particles are the electrons associated with P donors in Si. In the absence of interactions their quantum states develop coherently. The spatial extent of the qubit electrons is indicated by the localized wavefunctions W_{A} and W_{B}. The controlled interaction required to produce entanglement between the qubits A and B is furnished by a third, control system C, containing one or more additional electrons. In this embodiment the control system C comprises one electron initially bound to a much deeper trap, i.e., one with a larger excitation energy, for example a rare earth ion, such as Er³⁺. When this third defect is in its ground state the wavefunction of the control electron(s) is localised in state W_{CG} which is compact, and does not have sufficient spatial extent to interact with the qubits. The control system C can be excited into other states, however, whether a charge transfer state to an orbit largely associated with the two shallow donors, or simply a diffuse excited state. In this excited state, the C system's wavefunction W_{CE} is such that it can interact significantly with both qubit electrons A and B.

The gate protocol consists of controlled excitation and de-excitation of the electronic system C, so as to produce an effective two-qubit quantum gate. This excitation and de-excitation of C is performed in such a way that, at the end of the gate protocol, the two qubits are entangled with each other, and the control electron(s) has been returned to its ground state, and is not entangled with either qubit. The excitation can be performed with electromagnetic radiation provided by, for example, a pulsed laser tuned so as to appropriately excite the control electron system, thereby providing contrast between “on” (excited control electron) and “off” (no excited control electron) in coupling the two spins of the qubits. Electromagnetic radiation can, of course, be used to de-excite the control electron system, so that switching either between “on” and “off” or vice versa can be fully controlled.

This embodiment needs no external electrodes to manipulate the interaction between the qubits. Such electrodes would be a source of potential fluctuations, and hence of decoherence. Consequently it is possible to isolate the qubit donors sufficiently, so that in this embodiment the qubits are encoded in electron spin rather than nuclear spin, which is advantageous because the manipulations of the quantum state can be performed much more rapidly.

This embodiment could, of course, be modified to use nuclear spin to encode the qubits A and B. The choice of nuclear or electronic spin depends on the detailed parameters of a specific system and on the operating conditions.

In this embodiment, the donor of the control electron(s) is preferred to be of different character from the qubit donors. What is needed is a substantial change in the nature of the interaction of the two spins through a change in wavefunction of electronic system C. The change could for example involve excitation from the compact f-states of a rare-earth ion to a more extended s or d state. Since the donor of the control electron(s) in this embodiment is a deep centre, then the excitation energy can be reasonably large, for example corresponding to infrared or optical energies (1 to 2 eV) and, in particular, much larger than thermal energies at ambient temperatures (which, at room temperature, are typically 0.025 eV). Therefore, room temperature operation of this gate is possible. In this embodiment, the contrast between the off (control donor electronic system C in its ground state) and on (excited control of C) can be made extremely large by a suitable choice of states, so there is less need to take special action to ensure the qubit is unaltered when it should remain so.

With this embodiment of the invention it is possible (a) to excite, by laser or ultrasonics (e.g. GHz frequencies) or the combination of laser radiation and ultrasonics, the or each control electron and return it to its ground state so as to leave it unentangled with the qubits; (b) to simultaneously exploit the electron-qubit interaction so as to maximally entangle the two qubits; and (c) to select parameters such as by the choice of: the particular rare earth ion; the donor or acceptor; the band offsets between materials (e.g. between Si and the SiO₂ matrix described below); the applied fields; and the duration of and interval between exciting and de-exciting electromagnetic radiation pulses, in order to produce several types of universal quantum gate, to an acceptable level of accuracy.

Decoherence will depend in part on the interactions between impurities and defects, including those which are not part of the gate itself. A further embodiment of the invention, which can reduce decohering processes, is to fabricate the qubit and control donors in nanocrystals or nanostructures. This reduces phonon-induced homogeneous broadening because in this implementation there will be no phonons of energy suitable for 1-phonon processes. It has long been recognised that there are no lattice vibrational modes with wavelengths longer than a length determined by the size of the nanocrystal (cf. Paramagnetic Relaxation in Small Crystals. A M Stoneham 1965 Sol. St. Comm. 3, 71-73).

A further embodiment of the invention, which does not require a control donor, will now be described. In this further embodiment, as before, two suitable donor atoms, P for example, are placed at a suitable separation in Si, The qubits are encoded in their nuclear spins, and, as before, control is provided by electronic excitation. Each fixed P atom contributes one donor electron to a set of states of molecular character located at the donors. The controllable interaction between the spins comes from interaction via the electronic system, especially via an electron spin S through the contact interactions A₁I₁•S and A₂I₂•S, where A₁ is approximately proportional to the charge density of the electron with spin S at the site of nuclear spin I₁, and similarly for A₂. Thus, whenever the charge density of the electron at the qubit nuclei is changed, the interaction between the two qubit nuclear spins is altered. In particular, molecular states of one type [1] cause strong interactions between the nuclear spins I₁ and I₂, whereas molecular states of another type [2] do not. Thus, laser excitation of one of the donated electrons from a type [2] state to a type [1] state allows control of the nuclear spin-spin interaction, and consequently control of the qubit entanglement.

As a specific illustration of this embodiment, consider two P atoms at a chosen separation in silicon. Each P atom is a donor: it has one more electron than the Si atom it replaces so, once it has formed bonds to its Si neighbours in the crystal, there is an extra electron. This extra “donor” electron moves around the positively-charged P core (P has one more proton than Si) very much in the way that an electron moves around a proton in a free H atom. One major difference is in length and S energy scales: for P in Si, the electron orbit has a mean radius nearly two orders of magnitude greater than that for a free H atom. Correspondingly, the ionisation energy of the donor is nearly three orders of magnitude smaller than that of the free H atom. Thus, in silicon, an isolated shallow donor in Si has a binding energy of order 0.1 eV and its electron has a wavefunction of approximate extent 10 nm (the orbital radius) in the ground state. There are well-defined excited states (labelled by principal quantum number n, analogous to the free H atom) with extent larger by a factor of order n (thus, of order 30nm for n=3).

The analogy with an H atom is useful when thinking of the two P atoms at spacing L. This pair of donors will have electrons which interact significantly when their separation is less than or of the order of the orbital radius. But, since the orbital radius depends on the degree of electronic excitation, so the interaction with the electrons associated with donors at given spacing L will depend on the degree of electronic excitation. The interaction between the elections, just described, is important, but is not itself the interaction between the nuclear spins.

Referring to FIG. 2, FIG. 2(a) shows the electron density in the ground state. The nuclei, which encode the qubits are represented as black dots. The two electrons orbit them in states in which density is concentrated at one nucleus or the other. FIG. 2(b) shows an excited state in which electron density is shared between both nuclei, leading to enhanced nucleus-nucleus coupling.

For use as part of a quantum computer, a relatively long lifetime is needed in the excited state, since it should be able to last whilst a number of computer operations take place. Typical optical excited state lifetimes are tens of nanoseconds, and spin-forbidden states can often have microsecond lifetimes, and these lifetimes are long enough to be useful. However, if the excited state wavefunction suffers decoherence, whether by decay or dephasing, the qubits would be expected to be incoherently coupled, and perhaps not entangled (the magnetic analogue would be a noisy J gate). If so, a short excitation period is to be favoured. Overall, the preferred characteristics are strong excited-state qubit coupling and weak coupling of qubits to all other states. There is a compromise between (a) large interactions which lead to rapid inter-gate coupling and (b) large interactions which lead to rapid decoherence and (c) large interactions which lead to inhomogeneous broadening (which may or may not be useful). Such interactions can be used to determine aspects of design, such as the physical spacing of gates in the quantum computer.

Although all the above embodiments have been described in terms of donors, such as P in silicon, this is purely an example. Other examples of donors where used for the control electron system include Bi and As, and for the qubits many rare earth ions are suitable. It is of course also understood that the control electron system and/or the qubit spin system could comprises one or more holes, in which case the dopant species would an acceptor, for example In could be used as an acceptor for providing holes for the control electron system and A1 could be an acceptor for the qubits. Diamond or silicon carbide could be used instead of silicon.

A further embodiment of the invention allows the linking of qubits into a network, so that, for example, a series of qubits P, Q, R, S etc can be linked in controlled combinations of 2-qubit gates PQ, QR, PR etc. The architecture is illustrated in FIG. 3. Each qubit is represented by a small circle—the location, for example of a P donor in the Si substrate—and the control donors are represented by crosses. A 3-dimensional lattice of qubits and control donors is illustrated. The linking of adjacent gates into networks can be achieved by the selective excitation of the control particle which couples adjacent qubits. The standard approach to selectivity is based on choice of excitation frequency, combined with the focussing of light. However, it is hard to confine the exciting laser's effect to a region of space much smaller than its diffraction limit—about a cubic wavelength of laser light—and a region of this size may contain many thousands of gates at realistic donor densities.

According to this embodiment of the invention this problem is overcome by giving each qubit and each control donor within a region addressable by the electromagnetic radiation a unique environment, specified by up to three fields F₁, F₂ and F₃, which are ramped in up to three orthogonal directions. These can be suitable electric, magnetic or stress fields, chosen in such a way that the resonant frequency of each control donor, which depends on these fields, has a unique value within this region. In this way spatial and energy (frequency) discrimination of each electronic control system is provided to enable selective addressing. In FIG. 3, F₁ increases in the z direction, but is constant in the x and y directions, F₂ is constant in the y and z directions, but increases in the x direction, and F₃ is constant in the x and z direction but increases in the y direction. These fields can be time-dependent, and need not have constant field gradients. Every control system donor within the region defined by the lasers' diffraction limit should experience its own unique combination of up to three fields F₁, F₂ and F₃. Thus, the excitation of a specific control donor, made selective by the above methods leads to controlled communication between given qubits. Furthermore, each qubit itself has a unique environment, and may therefore be addressed individually. Such individual manipulations are what is required for the proper operation of a set of A gates, since the same fields can also affect the characteristic energies of one-qubit transitions, for example through changes in g-factors and hyperfine constants.

The variation of excitation energy with position can take one of a number of forms and, at least in some cases, need not require the very accurate placing of the gate atoms with extreme accuracy at specific sites chosen in advance. The preferred gate-building processes creates more gates than are needed, and certain of these are selected when the gates are to be linked together. Selection would be needed when the gates are embedded in a glassy host, such as a silica glass optical fibre, when the inhomogeneity of the glass will lead to variations in transition energies from the site of one gate to another.

The field or fields leading to variations in excitation energy from one site to another can be a conventional applied field applied by external means, like an electric field applied using suitable electrodes, or an applied magnetic field, or a stress field applied through an anvil or an indenter, or an ultrasonic wave, such as a transient pulse. The field may also be built in to the quantum computer through some designed mesostructure or microstructure. There are many ways to introduce mesostructure on the scale of a few tens to thousands of nanometers (see, e.g., A M Stoneham 1975 pps 1121-1235 of US-ERDA-CONF-751006P1 [edited M T Robinson and F W Young]). Combinations of the same or different fields in the different directions can be used.

One specific embodiment for achieving a spatially varying stress field is to use misfit dislocations. When a thin crystalline film is grown on a substrate with a suitably different lattice spacing, the film develops an approximately regular array of line defects, the so-called mismatch dislocations, to respond to this mismatch, as shown in FIG. 4. These dislocations have spacings of nanometres to microns, depending on the degree of mismatch. The specific examples are illustrative only, but show that it is possible to create systematic variations in strain fields on a scale of tens to hundreds of nanometres or more. The dislocations create static strain fields which will have a magnitude and space variation convenient for the combined spatial and frequency discrimination needed. Such mismatch dislocations are easy to produce in a useful form.

The implementations of the qubits is not limited to those described above and can be based, for example, on nuclear spins, or electron spins, or even on other “effective” spins, such as defects which can be found in a number of similar orientations, or other suitable systems with several distinct internal states. Typically, the gate comprises a small number of impurity atoms or defects in a host matrix. Some or all of this group of impurities or defects can be localised within a region of the host with chosen properties different from the normal host, e.g., a region of Si within an SiO₂ matrix, or a narrow band-gap carbon-based material in a diamond matrix. It is particularly preferred that the qubits are in a medium surrounded by a different medium such that there is a sufficiently high band offset to confine the electron system.

To achieve improved contrast between the coupling and isolation of the qubit states, i.e. between “on” (excited control electron system) and “off” (no excited control electron system) it is possible to tailor the wavefunctions to ensure greater differentiation between the “on” (excited) and “off” (ground) states. “Tailoring” in this context means combining solutions of the Schrödinger equation with microelectronic design and engineering to create a nanoscale physical structure which optimises the on/off differences. An example of an embodiment to achieve this is in the case of P donors in Si, is to create a narrow channel of Si within an SiO₂ matrix. The energy offset between the Si conduction band and the SiO₂ conduction band is large, so the electrons will be confined within the narrow channel.

In the case where dopant atoms of donor or acceptor species are used to provide the control electron system, the dopant atoms need not be in the same material as the qubit units. For example, a multilayer structure can be used in which the dopants are in one layer and the qubit units are in a different layer such that there is an interface between the two layers. When in the excited state, the control electron system from the dopant atoms can move into the layer containing the qubits to facilitate interaction therebetween. Alternatively, a vertical sandwich structure could be used comprising in the following order a first layer with a first qubit unit, a second layer with the control electron system, and a third layer with a second qubit unit.

There are two clear technical problems: firstly how to make the spacing of the two donors what one wishes, and secondly how to improve the contrast between the two states.

According to a further embodiment of the invention, a nanotechnology approach is used to address the problem of creating donors spaced apart by a selected distance. This embodiment involves the following a series of steps:
(1). Create a region of silicon by low-energy electron irradiation, using an electron beam, of optical fibre composed of SiO₂;
(2). Absorb on that Si a molecule in which a specific P—P spacing can be ensured (e.g. a buckeyball pair, or simply a rigid organic molecule);
(3). Oxidise the surface gently, so as to burn off the C and to oxidise the Si to SiO₂.

It may further be desirable to leave a “track” of Si between the donors.

1. A gate for quantum information processing comprising:
at least two units each having a plurality of states useable for representing quantum information; and
an electron system having at least a first state and a second state, which states provide different amounts of interaction between said units, wherein the electron system is switchable by means of electromagnetic radiation between the first and second states to control the interaction between the units.

2. A gate according to claim 1, wherein the information-representing units are systems having nuclear spin or electronic spin or are reorientable defects.

3. A gate according to claim 1, wherein the first and second states are the ground state and an excited state of the electron system.

4. A gate according to claim 1, wherein the second state has a larger spatial extent than the first state.

5. A gate according to claim 1, wherein when the electron system is in the first state the interaction between the units is substantially eliminated and when in the second state the interaction is enhanced.

6. A gate according to claim 1, wherein the electron system comprises one or more electrons provided by at least one donor atom.

7. A gate according to claim 6, wherein the at least one donor atom comprises a deep-donor.

8. A gate according to claim 1, wherein the electron system comprises one or more holes resulting from at least one acceptor atom receiving an electron.

9. A gate according to claim 8, wherein the at least one acceptor atom comprises a deep-acceptor.

10. A gate according to claim 1, wherein the or each donor or acceptor atom is located between the information-representing units.

11. A gate according to claim 1, wherein the or each donor or acceptor atom is separated from the information-representing units by an interface.

12. A gate according to claim 1, wherein the information-representing units comprise donor atoms, of which the nuclear spin states are useable for representing quantum information, and the electron system comprises one or more electrons from said donor atoms.

13. A gate according to claim 1, wherein the information-representing units comprise acceptor atoms, of which the nuclear spin states are useable for representing quantum information, and the electron system comprises one or more holes provided by said acceptor atoms.

14. A gate according to claim 1, wherein the energy difference between the first and second states is greater than the energy associated with the information of the information-representing units.

15. A gate according to claim 1, wherein the energy difference between the first and second states is greater than 0.025 eV.

16. A gate according to claim 1, wherein the gate is provided in a nanocrystal.

17. A gate according to claim 1, wherein the information-representing units are provided in an Si channel in an SiO₂ matrix.

18. A gate according to claim 1, wherein the electromagnetic radiation is time dependent, preferably a laser pulse.

19. An array of gates, for quantum information processing, comprising:
means for applying at least one field over the array, which field shifts the energy of transitions used to control states, and wherein the or each field varies spatially, so that different portions of the array are selectively controllable.

20. An array of gates according to claim 19, wherein the at least one field comprises one or more of electric field, magnetic field and stress field.

21. An array of gates according to claim 19, wherein a stress field is appliable externally as one of an ultrasonic or acoustic pulse.

22. An array of gates according to claim 19, wherein a stress field is the result of misfit dislocations.

23. An array of gates according to claim 19, wherein more than one field is appliable, and the directions in which the fields vary spatially are different from each other.

24. An array of gates according to claim 19, wherein at least one of the fields is time-dependent.

25. An array of gates according to claim 19, wherein selective control of qubit-qubit interaction or intra-qubit control is enabled.

26. A method of selectively controlling gates in an array of gates, for quantum information processing, comprising:
applying at least one field over the array, which field shifts the energy of transitions used to control states, and wherein the or each field varies spatially, so that different portions of the array are selectively controllable.

27. A method of fabricating a gate comprising the steps of:
(1) Creating a region of silicon by low-energy electron irradiation of optical fibre composed of SiO₂;
(2) Absorbing on that Si a molecule including two atoms which can function as donors in Si and which have a specific interatomic spacing in that molecule;
(3) Oxidising the surface, so as to burn off the undesired atoms from the molecule and to oxidise the Si to SiO₂.

28. A method according to claim 27, wherein the molecule is a buckeyball pair, or a rigid organic molecule.
